(19) United States
(12) Patent Application Publication
(10) Pub. No.: US 2007/0152765 A1
(43) Pub. Date: Jul. 5, 2007

(54) Clock signal generating circuit

(75) Inventor: Chun-Hung Chen, Tu-cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: Hon Hai Precision Industry Co., LTD

(21) Appl. No.: 11/521,923

(22) Filed: Sep. 15, 2006

(30) Foreign Application Priority Data
Dec. 30, 2005 (CN) 200510121395.1

(51) Int. Cl. H03B 1/00

(52) U.S. Cl. 331/74

(57) ABSTRACT

A clock signal generating circuit is provided. The clock signal generating circuit includes a clock signal generator and a filter circuit. The clock signal generator generates a clock signal of a predetermined frequency. The filter circuit is electronically connected to the clock signal generator to receive the clock signal. The filter circuit has a resonance frequency equaling the predetermined frequency for eliminating harmonic components of the clock signal having a higher frequency than the predetermined frequency, and outputs a filtered clock signal.

### BACKGROUND OF THE INVENTION

1. Field of the Invention

The present invention relates to a clock signal generating circuit, and particularly to a clock signal generating circuit causing little electromagnetic interference.

2. Description of Related Art

Use of digital clock-controlled signal-processing devices in various fields of application, particularly in computer systems, for the display or control of diverse functions requires clock signal generators. However, interference signals are also produced in a high-frequency clock signal generator, directly or via the connected supply or signal lines, in a wide frequency range. The interference signals may interfere with the operation of nearby devices.

Some methods are known in the art whereby a plurality of damper resistors or circuits composed of resistors and capacitors are used with the clock signal generator to reduce electromagnetic interference to adjacent electronic equipment. However, such methods do not eliminate high frequency harmonic components of clock signals, thereby strong electromagnetic interference still exists.

What is needed, therefore, is a clock signal generating circuit that causes little electromagnetic interference to nearby electronic devices.

### SUMMARY OF THE INVENTION

A clock signal generating circuit is provided. In a preferred embodiment, the clock signal generating circuit includes a clock signal generator and a filter circuit. The clock signal generator generates a clock signal of a predetermined frequency. The filter circuit is electronically connected to the clock signal generator to receive the clock signal. The filter circuit has a resonance frequency equaling the predetermined frequency for eliminating harmonic components of the clock signal having a higher frequency than the predetermined frequency, and outputs a filtered clock signal.

Other advantages and novel features will become more apparent from the following detailed description when taken in conjunction with the accompanying drawings, in which:

### BRIEF DESCRIPTION OF THE DRAWINGS

FIG. 1 is a circuit diagram of a clock signal generating circuit, in accordance with a first preferred embodiment of the present invention;

FIG. 2 is a graph of electromagnetic interference intensity produced by the clock signal generating circuit of FIG. 1 and a clock signal generator without a filter circuit; and

FIG. 3 is a circuit diagram of a clock signal generating circuit, in accordance with a second preferred embodiment of the present invention.

### DETAILED DESCRIPTION OF THE INVENTION

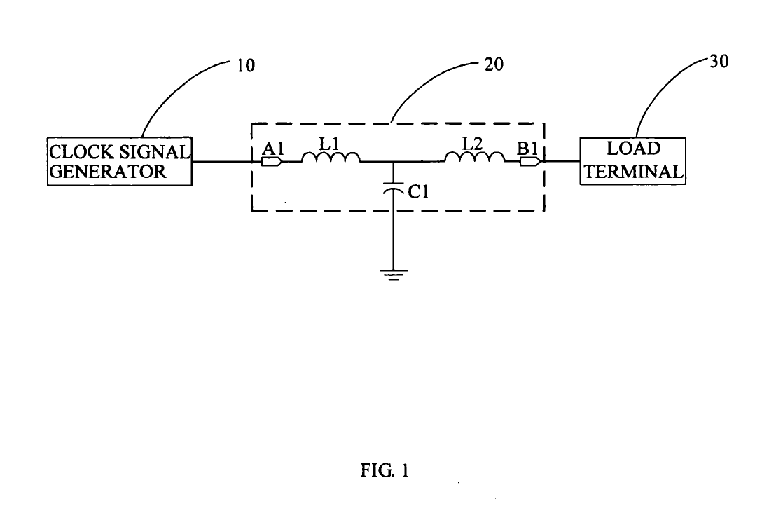

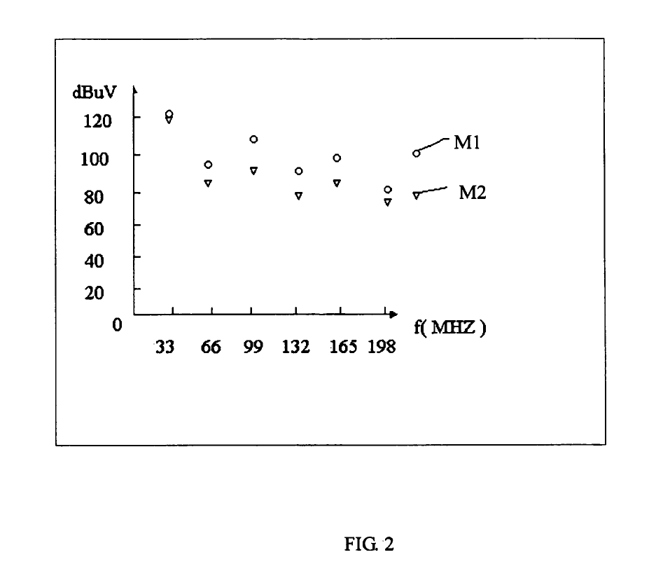

FIG. 1 shows a clock signal generating circuit, in accordance with a first preferred embodiment of the present invention. The clock signal generating circuit includes a clock signal generator 10 and a filter circuit 20. The clock signal generator 10 provides a clock signal of a predetermined frequency f1 to a load terminal 30. The filter circuit 20 includes an input terminal A1, a first inductor L1, a second inductor L2, a capacitor C1, and an output terminal B1. The first inductor L1 and the second inductor L2 are connected in series between the input terminal A1 and the output terminal B1. The capacitor C1 is connected between a node between the first inductor L1 and the second inductor L2 and ground. The input terminal A1 is connected to the clock signal generator 10. The output terminal B1 outputs a filtered clock signal to the load terminal 30. A resonance frequency F1 of the filter circuit 20 is found using the follow equation: F1=1/(4*π*\sqrt{L*C})

Wherein L is an inductance of the first inductor L1, and C is a capacitance of the capacitor C1. The inductance of the first inductor L1 equals an inductance of the second inductor L2. The inductance L and the capacitance C can be selected to make the resonance frequency F1 equal the predetermined frequency f1. Therefore the predetermined frequency f1 component of the clock signal is output from the output terminal B1, while the filter circuit 20 eliminates the harmonic components having a higher frequency than the predetermined frequency f1. The filter circuit 20 is set at the clock signal. Therefore electromagnetic interference produced by the high frequency harmonic components is eliminated at the sending terminal of the clock signal. As shown in FIG. 2, intensity of electromagnetic interference M2 produced by the clock signal generating circuit of FIG. 1 is lower than intensity of electromagnetic interference M1 produced by a clock signal generator without a filter circuit. Furthermore, the number of inductors and capacitors can be changed accordingly to filter any combination of unwanted signals from the desired clock signal.

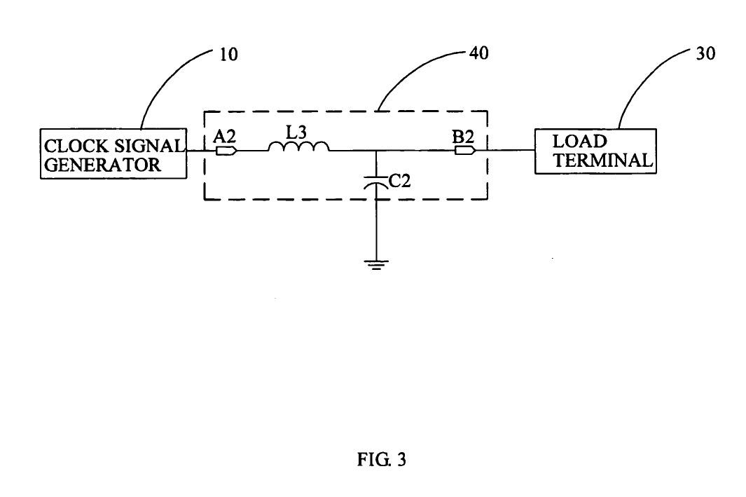

FIG. 3 shows a clock signal generating circuit, in accordance with a second preferred embodiment of the present invention. The filter circuit 40 includes an input terminal A2, an inductor L3, a capacitor C2 and an output terminal B2. The inductor L3 is connected between the input terminal A2 and the output terminal B2. The capacitor C2 is connected between the output terminal B2 and ground. The input terminal A2 is connected to the clock signal generator 10. The output terminal B2 outputs a filtered clock signal to the load terminal 30. A resonance frequency F2 of the filter circuit 40 is found using the follow equation: F=1/(2*π*\sqrt{L*C})

Wherein L is an inductance of the inductor L3, and C is a capacitance of the capacitor C2. The inductance L and the capacitance C are adjusted to make the resonance frequency F2 equal the predetermined frequency f1. Therefore the predetermined frequency f1 component of the clock signal is output from the output terminal B2, while the filter circuit 40 eliminates harmonic components having a higher frequency than the predetermined frequency f1.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. A clock signal generating circuit comprising:
a clock signal generator for generating a clock signal of a predetermined frequency; and
a filter circuit electronically connected to the clock signal generator to receive the clock signal, the filter circuit having a resonance frequency equaling the predetermined frequency for eliminating harmonic components of the clock signal having a higher frequency than the predetermined frequency, and outputting a filtered clock signal.

2. The clock signal generating circuit as claimed in claim 1, wherein the filter circuit comprises an input terminal, a first inductor, a second inductor, a capacitor, and an output terminal, the first inductor and the second inductor connected in series between the input terminal and the output terminal, the capacitor connected between a node between the first inductor and the second inductor and ground, the input terminal connected to the clock signal generator, and the output terminal outputting the filtered clock signal.

3. The clock signal generating circuit as claimed in claim 2, wherein an inductance of the first inductor equals an inductance of the second inductor.

4. The clock signal generating circuit as claimed in claim 1, wherein the filter circuit comprises an input terminal, an inductor, a capacitor, and an output terminal, the inductor connected between the input terminal and the output terminal, the capacitor connected between the output terminal and ground, the input terminal connected to the clock signal generator, and the output terminal outputting the filtered clock signal.

5. A clock signal generating circuit comprising:
a clock signal generator for providing a clock signal of a predetermined frequency to a load terminal; and
a filter circuit comprising at least a capacitor and at least an inductor, the filter circuit being set at the clock signal generator to receive the clock signal, and having a resonance frequency configured for eliminating harmonic components of the clock signal having a higher frequency than the predetermined frequency.

6. The clock signal generating circuit as claimed in claim 5, wherein the filter circuit comprises an input terminal, a first inductor, a second inductor, a capacitor, and an output terminal, the first inductor and the second inductor connected in series between the input terminal and the output terminal, the capacitor connected between a node between the first inductor and the second inductor and ground, the input terminal connected to the clock signal generator, and the output terminal outputting a filtered clock signal.

7. The clock signal generating circuit as claimed in claim 6, wherein an inductance of the first inductor equals an inductance of the second inductor.

8. The clock signal generating circuit as claimed in claim 5, wherein the inductor connected between an input terminal and an output terminal, the capacitor connected between the output terminal and ground, the input terminal connected to the clock signal generator, and the output terminal outputting a filtered clock signal.

9. A clock signal generating circuit comprising:
a clock signal generator for providing a clock signal with a predetermined frequency component and harmonic components; and
a filter circuit being set at the clock signal generator to receive the clock signal, the filter circuit comprising at least an inductor for transmitting the predetermined frequency component of the clock signal to a load terminal, and at least a capacitor for transmitting harmonic components of the clock signal having a higher frequency than the predetermined frequency to ground.

10. The clock signal generating circuit as claimed in claim 9, wherein the filter circuit comprises a pair of inductors connected in series between the clock signal generator and the load terminal.
